(19) United States
(12) Patent Application Publication
(10) Pub. No.: US 2026/0182319 A1
(43) Pub. Date: Jun. 25, 2026

(54) METHOD FOR FORMING SEMICONDUCTOR STRUCTURE

(71) Applicant: Winbond Electronics Corp., Taichung City (TW)

(72) Inventor: Ching-Yung WANG, Taichung City (TW)

(21) Appl. No.: 19/360,156

(22) Filed: Oct. 16, 2025

(30) Foreign Application Priority Data
Dec. 25, 2024 (TW) 113150615

(51) Int. Cl. H01L 21/762; H10D 64/01

(52) U.S. Cl. CPC H10W 10/17; H10D 64/035; H10W 10/0145

(57) ABSTRACT

A method for forming a semiconductor structure, including providing a substrate, sequentially forming a first floating gate layer and a mask layer over the substrate, etching the substrate to form a trench and to define an active region in the substrate, forming a first isolation structure in the trench and extending into the substrate, forming a spacer on a sidewall of the mask layer to form a first opening over the first isolation structure, and forming a second isolation structure to fill the first opening. The method includes removing the mask layer and the spacer to form a second opening, forming a second floating gate layer to fill the second opening, removing the second isolation structure to expose the top surface of the first isolation structure, conformally forming an inter-gate dielectric layer over the substrate, and forming a control gate layer on the inter-gate dielectric layer.

### CROSS REFERENCE TO RELATED APPLICATIONS

This application claims priority of Taiwan patent application No. 113150615, filed Dec. 25, 2024, the entirety of which is incorporated by reference herein.

### TECHNICAL FIELD

The present disclosure relates to semiconductor process technology, and, in particular, it relates to a method for forming a floating gate of a flash memory device.

### BACKGROUND

To increase component density and improve the overall performance of flash memory devices, current technologies for manufacturing flash memory devices continue to advance toward scaling-down such devices. However, as the minimum feature size continues to decrease, various challenges arise. For example, as the dimensions of the floating gate are scaled-down, it becomes necessary to simplify the process of forming the floating gate in order to enhance the process margins and improve the coupling ratio between the floating gate and the control gate. Accordingly, the industry still needs to improve methods of manufacturing flash memory devices to address issues associated with the miniaturization of such devices.

### BRIEF SUMMARY

An embodiment of the present disclosure provides a method for forming a semiconductor structure, including providing a substrate, sequentially forming a first floating gate layer and a mask layer over the substrate, and etching the substrate to form a trench and to define an active region in the substrate. The method includes forming a first isolation structure in the trench and extending into the substrate, forming a spacer on a sidewall of the mask layer to form a first opening over the first isolation structure, and forming a second isolation structure to fill the first opening. The method includes removing the mask layer and the spacer to form a second opening, forming a second floating gate layer to fill the second opening, removing the second isolation structure to expose the top surface of the first isolation structure, conformally forming an inter-gate dielectric layer over the substrate, and forming a control gate layer on the inter-gate dielectric layer.

### BRIEF DESCRIPTION OF THE DRAWINGS

Aspects of the present disclosure are best understood from the following detailed description when read with the accompanying figures.

FIGS. 1, 2, 3, 4, 5, 6, 7, 8, 9, 10, 11, 12, 13, 14, and 15 illustrate cross-sectional views of the intermediate stages of forming the semiconductor structure according to the embodiments of the present disclosure.

### DETAILED DESCRIPTION

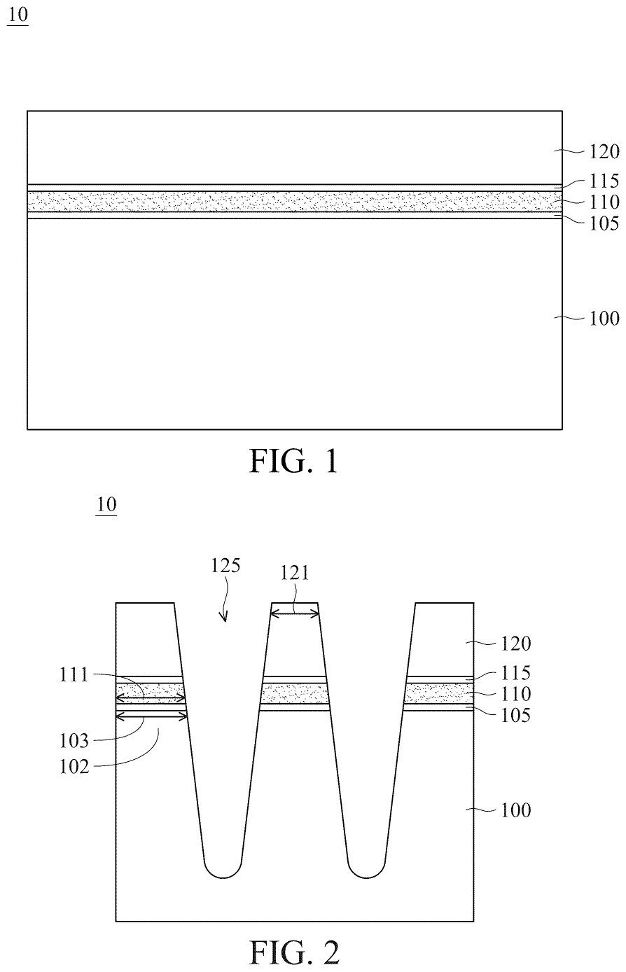

Referring to FIG. 1, FIG. 1 illustrates a cross-sectional view of a semiconductor structure 10. A substrate 100 is provided. In some embodiments, the substrate 100 may be an elemental semiconductor substrate, a compound semiconductor substrate, or an alloy semiconductor substrate. In other embodiments, the substrate 100 may be a semiconductor-on-insulator (SOI) substrate. The SOI substrate may include a base substrate, a buried oxide (BOX) layer disposed on the base substrate, and a semiconductor layer disposed on the buried oxide layer.

Still referring to FIG. 1, a tunnel oxide layer 105, a first floating gate layer 110, a buffer layer 115, and a mask layer 120 are sequentially formed over the substrate 100. The buffer layer 115 may protect the first floating gate layer 110 during the etching of the mask layer 120. In some embodiments, the tunnel oxide layer 105 may be formed by a thermal oxidation process, a chemical vapor deposition (CVD) process, an atomic layer deposition (ALD) process, or a combination thereof. In some embodiments, the first floating gate layer 110 may be formed by a chemical vapor deposition process or a similar deposition process. In some embodiments, the buffer layer 115 and the mask layer 120 may be formed by a chemical vapor deposition process, an atomic layer deposition process, or a combination thereof. In some embodiments, the tunnel oxide layer 105 is formed of an oxide material, such as silicon oxide. In some embodiments, the first floating gate layer 110 may be formed of doped polysilicon, a metal, a polycide (i.e., a polycrystalline metal silicide), or a combination thereof. In some embodiments, the buffer layer 115 is formed of an oxide material, such as silicon oxide. In some embodiments, the mask layer 120 is formed of a nitride material, such as silicon nitride.

Referring next to FIG. 2, FIG. 2 illustrates a cross-sectional view of the semiconductor structure 10 forming a trench 125. An etching process is performed on the substrate 100 to form the trench 125. The trench 125 penetrates through the mask layer 120, the buffer layer 115, the first floating gate layer 110, and the tunnel oxide layer 105, and the trench 125 extends into the substrate 100. After forming the trench 125, the trench 125 thereby defines an active region 102 in the substrate 100. In some embodiments, the top width 121 of the mask layer 120 is less than the bottom width 111 of the first floating gate layer 110. In some embodiments, the bottom width 111 of the first floating gate layer 110 is less than or equal to the top width 103 of the active region 102. In some embodiments, the etching process may include an anisotropic etching process (or directional etching process), such as a reactive ion etching (RIE) process, a plasma etching process, an inductively coupled plasma (ICP) etching process, or a dry etching process that is a combination thereof.

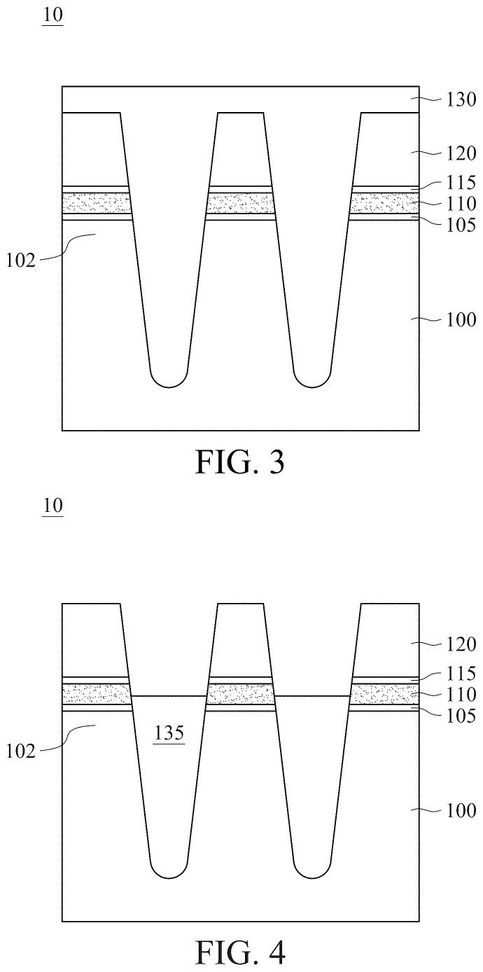

Referring to FIG. 3, FIG. 3 illustrates a cross-sectional view of the semiconductor structure 10 forming a first isolation material layer 130. After forming the trench 125, the first isolation material layer 130 is formed to overfill the trench 125. In some embodiments, the first isolation material layer 130 may be formed by a chemical vapor deposition (CVD) process, an atomic layer deposition (ALD) process, or a combination thereof. In some embodiments, the first isolation material layer 130 is formed of an oxide material, such as silicon oxide.

Referring next to FIG. 4, FIG. 4 illustrates a cross-sectional view of the semiconductor structure 10 forming a first isolation structure 135. After forming the first isolation material layer 130, a planarization process such as chemical mechanical polishing (CMP) may be performed on the first isolation material layer 130 to expose the top surface of the mask layer 120. Subsequently, an etch-back process is performed on the first isolation material layer 130 to form the first isolation structure 135. The first isolation structure 135 extends into the substrate 100. In some embodiments, performing the etch-back process includes adjusting the top surface of the first isolation structure 135 to be lower than the top surface of the first floating gate layer 110 and higher than the bottom surface of the first floating gate layer 110, which facilitates control over the formation of the floating gate in the memory device. In some embodiments, the etch-back process may include an anisotropic etching process (or directional etching process), such as a reactive ion etching (RIE) process, a plasma etching process, an inductively coupled plasma (ICP) etching process, or a dry etching process that is a combination thereof.

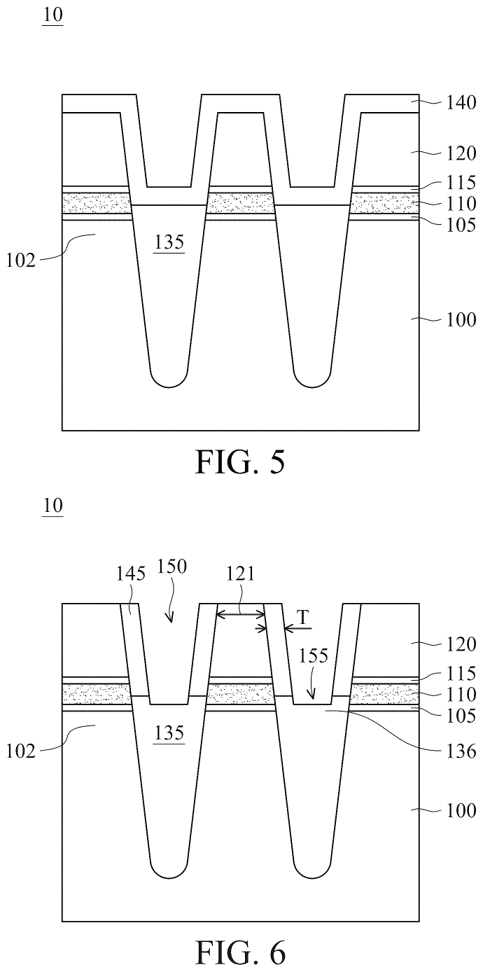

Referring to FIG. 5, FIG. 5 illustrates a cross-sectional view of the semiconductor structure 10 conformally forming a spacer material layer 140. The spacer material layer 140 is conformally formed over the substrate 100. In the embodiments of the present disclosure, the spacer material layer 140 (i.e., a subsequently formed spacer 145) is used to define the width of a floating gate of the memory device. In other words, the embodiments of the present disclosure simplify the floating gate formation process by forming the spacer material layer 140 and the subsequent spacer 145, thereby avoiding repeated patterning of the structure around the floating gate while maintaining the required dimensions of the floating gate. In some embodiments, the spacer material layer 140 may be formed by a chemical vapor deposition (CVD) process, an atomic layer deposition (ALD) process, or a combination thereof. In some embodiments, the spacer material layer 140 is formed of a nitride material, such as silicon nitride.

Referring to FIG. 6, FIG. 6 illustrates a cross-sectional view of the semiconductor structure 10 forming a spacer 145. An etching process is performed on the spacer material layer 140 to expose the respective top surfaces of the first isolation structure 135 and the mask layer 120, thereby forming the spacer 145. More specifically, the spacer 145 is formed on a sidewall of the mask layer 120. After forming the spacer 145, a first opening 150 is formed over the first isolation structure 135. In some embodiments, to avoid residue of the spacer material layer 140, the step of etching the spacer material layer 140 further includes forming a recess 155 at an upper portion 136 of the first isolation structure 135. In some embodiments, the spacer 145 is in direct contact with the first floating gate layer 110. In some embodiments, the etching process may include an anisotropic etching process (or directional etching process), such as a reactive ion etching (RIE) process, plasma etching, inductively coupled plasma (ICP) etching, or a dry etching process that is a combination thereof.

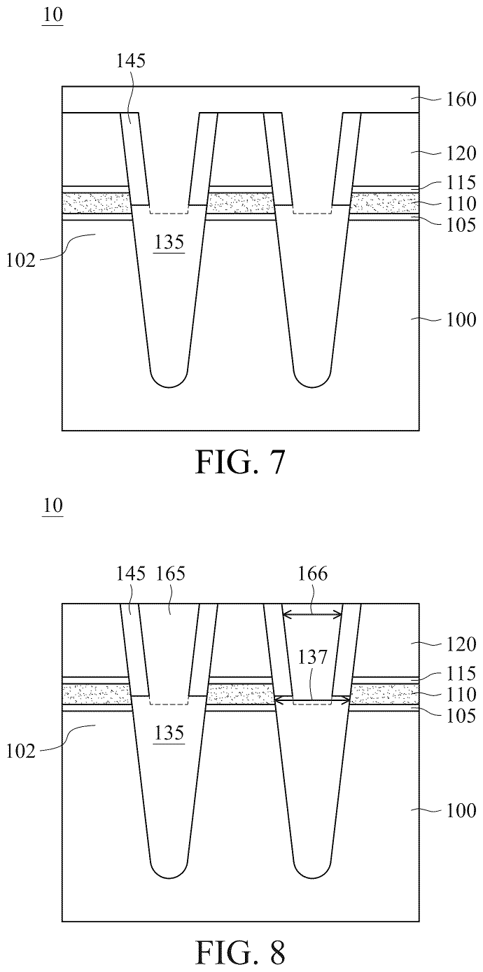

Referring next to FIG. 7, FIG. 7 illustrates a cross-sectional view of the semiconductor structure 10 forming a second isolation material layer 160. After forming the first opening 150, the second isolation material layer 160 is formed to overfill the first opening 150. In some embodiments, the second isolation material layer 160 completely fills the recess 155. In some embodiments, the second isolation material layer 160 may be formed by a chemical vapor deposition (CVD) process, an atomic layer deposition (ALD) process, or a combination thereof. In some embodiments, the second isolation material layer 160 is formed of an oxide material, such as silicon oxide.

Referring to FIG. 8, FIG. 8 illustrates a cross-sectional view of the semiconductor structure 10 forming a second isolation structure 165. After forming the second isolation material layer 160, a planarization process, such as chemical mechanical polishing (CMP), may be performed on the second isolation material layer 160 to form the second isolation structure 165. More specifically, the second isolation structure 165 fills the first opening 150. In some embodiments, after forming the second isolation structure 165, the second isolation structure 165 completely fills the recess 155. In some embodiments, the top width 166 of the second isolation structure 165 is less than the top width 137 of the first isolation structure 135. In some embodiments, the spacer 145 has a different etch selectivity from the first isolation structure 135 and the second isolation structure 165, and the mask layer 120 has the same etch selectivity as the spacer 145.

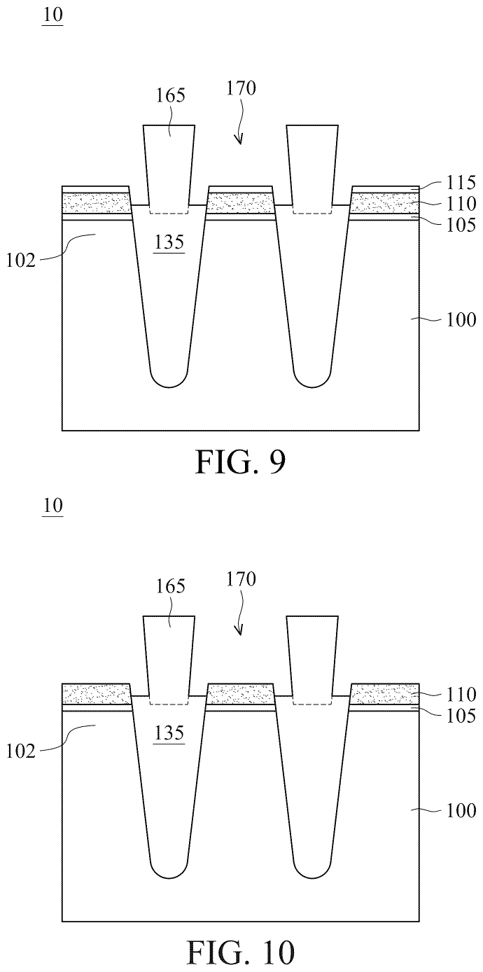

Referring next to FIG. 9, FIG. 9 illustrates a cross-sectional view of the semiconductor structure 10 forming a second opening 170. After forming the second isolation structure 165, the mask layer 120 and the spacer 145 are removed to form the second opening 170. More specifically, the second opening 170 is formed to expose a sidewall of the second isolation structure 165, the top surface of the buffer layer 115, and the top surface of a portion of the first isolation structure 135. The second opening 170 is used for forming a second floating gate layer 180, which is described in detail below. In some embodiments, the step of removing the mask layer 120 and the spacer 145 may include a dry etching process, a wet etching process, or a combination thereof.

Referring to FIG. 10, FIG. 10 illustrates a cross-sectional view of the semiconductor structure 10 removing the buffer layer 115. After removing the mask layer 120 and the spacer 145, the buffer layer 115 is further removed to expose the top surface of the first floating gate layer 110. In other words, the second opening 170 exposes the top surface of the first floating gate layer 110 and the top surface of a portion of the first isolation structure 135. The removal of the buffer layer 115 is followed by the formation of a second floating gate material layer 175, which is described in detail below.

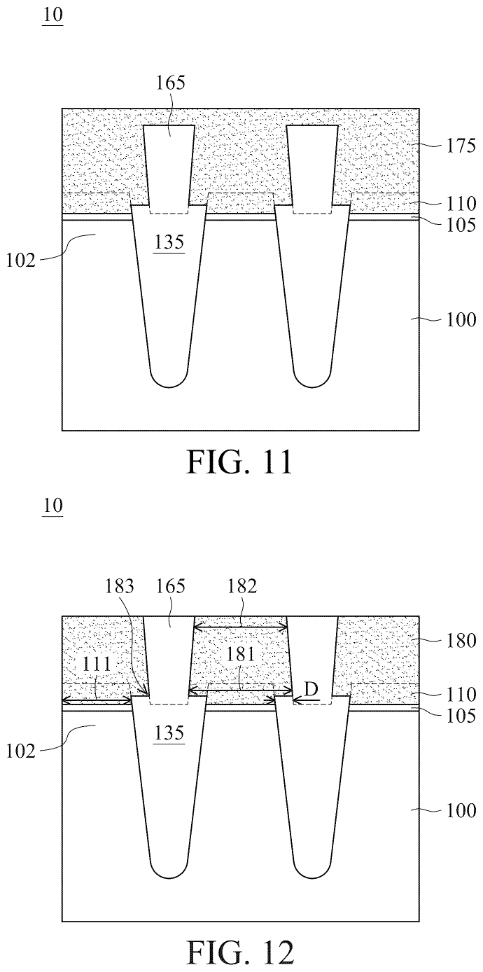

Referring next to FIG. 11, FIG. 11 illustrates a cross-sectional view of the semiconductor structure 10 forming a second floating gate material layer 175. The second floating gate material layer 175 is formed to overfill the second opening 170. In some embodiments, the second floating gate material layer 175 may be formed by a chemical vapor deposition (CVD) process or a similar deposition process. In some embodiments, the material of the second floating gate material layer 175 may include doped polysilicon, metal, polycide, or a combination thereof. In some embodiments, the material of the second floating gate material layer 175 may be the same as that of the first floating gate layer 110.

Referring to FIG. 12, FIG. 12 illustrates a cross-sectional view of the semiconductor structure 10 forming a second floating gate layer 180. After forming the second floating gate material layer 175, a planarization process, such as chemical mechanical polishing (CMP), may be performed on the second floating gate material layer 175 to form the second floating gate layer 180. In other words, the second floating gate layer 180 fills the second opening 170. In some embodiments, the bottom width 181 of the second floating gate layer 180 is greater than the bottom width 111 of the first floating gate layer 110. In some embodiments, the top width 182 of the second floating gate layer 180 is less than the bottom width 181 of the second floating gate layer 180. In some embodiments, the top width 182 of the second floating gate layer 180 is equal to the sum of the top width 121 of the mask layer 120 and twice a thickness T of the spacer 145. In some embodiments, the thickness T of the spacer 145 is equal to a distance D of a sidewall of the second floating gate layer 180 beyond a sidewall of the first floating gate layer 110. The first floating gate layer 110 and the second floating gate layer 180 may collectively be referred to as the floating gate. In some embodiments, the bottom of the second floating gate layer 180 has an acute angle 183. In some embodiments, the acute angle 183 is greater than 80 degrees and less than 90 degrees.

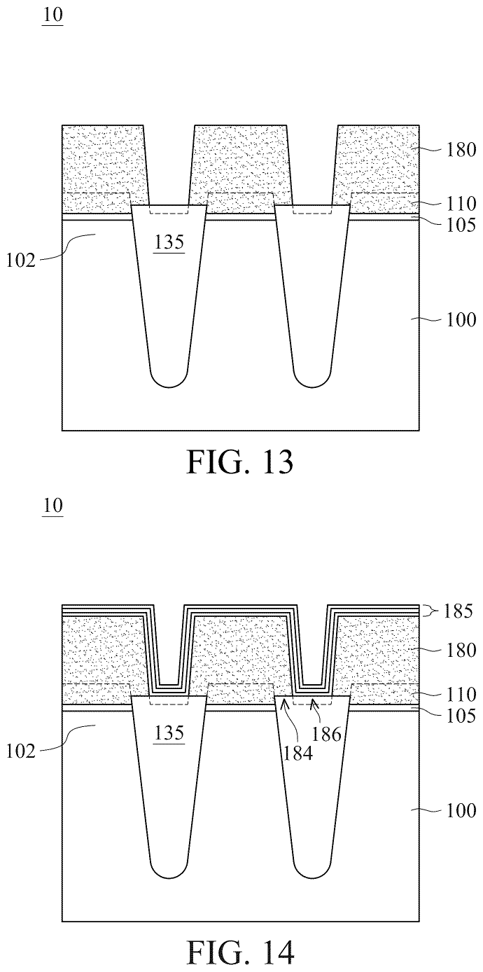

Referring to FIG. 13, FIG. 13 illustrates a cross-sectional view of the semiconductor structure 10 after removing the second isolation structure 165. The second isolation structure 165 is removed to expose the top surface of the first isolation structure 135 and sidewalls of the second floating gate layer 180. More specifically, in some embodiments, the top surface of the first isolation structure 135 filled in the recess 155 is exposed. In some embodiments, the step of removing the second isolation structure 165 may include an anisotropic etching process (or a directional etching process), such as a reactive ion etching (RIE) process, plasma etching, inductively coupled plasma (ICP) etching, or a dry etching process that is a combination thereof.

Referring to FIG. 14, FIG. 14 illustrates a cross-sectional view of the semiconductor structure 10 after forming an inter-gate dielectric layer 185. The inter-gate dielectric layer 185 is conformally formed over the substrate 100. In some embodiments, the bottom surface 186 of the inter-gate dielectric layer 185 is level with the lower surface 184 of the second floating gate layer 180. In some embodiments, the inter-gate dielectric layer 185 may be a single-layer structure or a multi-layer structure, and the material of the inter-gate dielectric layer 185 may include silicon oxide, silicon nitride, or a combination thereof. For example, the inter-gate dielectric layer 185 may have an oxide/nitride/oxide (ONO) structure. In some embodiments, the inter-gate dielectric layer 185 may be formed by a chemical vapor deposition (CVD) process, an atomic layer deposition (ALD) process, or a combination thereof.

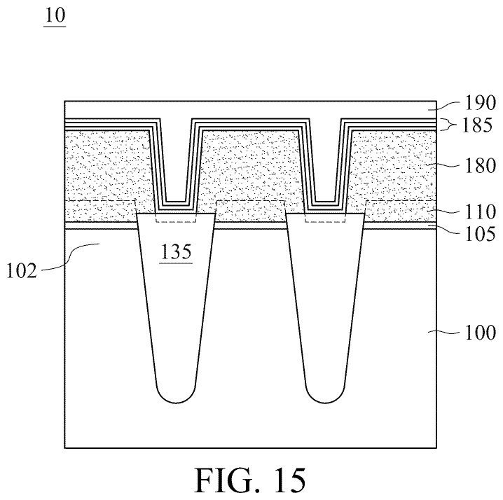

Referring to FIG. 15, FIG. 15 illustrates a cross-sectional view of the semiconductor structure 10 after forming a control gate layer 190. The control gate layer 190 is formed on the inter-gate dielectric layer 185. In some embodiments, the control gate layer 190 may be a single-layer or multi-layer structure, and the material of the control gate layer 190 may include polysilicon, metal, metal silicide, similar conductive materials, or a combination thereof. In some embodiments, the control gate layer 190 may be formed by a chemical vapor deposition (CVD) process, an atomic layer deposition (ALD) process, or a combination thereof.

After forming the control gate layer 190, additional processing steps may be subsequently performed to continue forming various components of the flash memory device, which are not described in detail herein.

In summary, the embodiments of the present disclosure provide a method for forming a semiconductor structure. The method simplifies conventional multi-patterning processes and facilitates the formation of scaled-down semiconductor structures. The method also improves the coupling ratio between the floating gate and the control gate, thereby enhancing the performance of the memory device. The floating gate formed according to the embodiments of the present disclosure may have straight and tapered sidewalls, which are beneficial for the subsequent formation of the inter-gate dielectric layer and the control gate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
providing a substrate;
sequentially forming a first floating gate layer and a mask layer over the substrate;
etching the substrate to form a trench and to define an active region in the substrate;
forming a first isolation structure in the trench and extending into the substrate;
forming a spacer on a sidewall of the mask layer to form a first opening over the first isolation structure;
forming a second isolation structure to fill the first opening;
removing the mask layer and the spacer to form a second opening;
forming a second floating gate layer to fill the second opening;
removing the second isolation structure to expose a top surface of the first isolation structure;
conformally forming an inter-gate dielectric layer over the substrate; and
forming a control gate layer on the inter-gate dielectric layer.

2. The method as claimed in claim 1, wherein forming the spacer on the sidewall of the mask layer further comprises:
conformally forming a spacer material layer over the substrate; and
etching the spacer material layer to expose the top surfaces of the first isolation structure and the mask layer and form the spacer.

3. The method as claimed in claim 2, wherein etching the spacer material layer further comprises:
forming a recess at an upper portion of the first isolation structure.

4. The method as claimed in claim 3, wherein after forming the second isolation structure, the second isolation structure completely fills the recess.

5. The method as claimed in claim 1, wherein forming the first isolation structure in the trench further comprises:
forming a first isolation material layer to overfill the trench;
planarizing the first isolation material layer to expose a top surface of the mask layer; and
etching back the first isolation material layer to form the first isolation structure,
wherein the top surface of the first isolation structure is lower than a top surface of the first floating gate layer and higher than a bottom surface of the first floating gate layer.

6. The method as claimed in claim 1, wherein before sequentially forming the first floating gate layer and the mask layer over the substrate, the method further comprises:
forming a tunnel oxide layer on the substrate, wherein the first floating gate layer is formed on the tunnel oxide layer.

7. The method as claimed in claim 1, wherein a bottom width of the first floating gate layer is less than or equal to a top width of the active region.

8. The method as claimed in claim 1, wherein a bottom width of the second floating gate layer is greater than a bottom width of the first floating gate layer.

9. The method as claimed in claim 1, wherein a top width of the second floating gate layer is less than a bottom width of the second floating gate layer.

10. The method as claimed in claim 1, wherein a top width of the second floating gate layer is equal to a sum of a top width of the mask layer and twice a thickness of the spacer.

11. The method as claimed in claim 1, wherein a bottom surface of the inter-gate dielectric layer is level with a lower surface of the second floating gate layer.

12. The method as claimed in claim 1, wherein the spacer is in direct contact with the first floating gate layer.

13. The method as claimed in claim 1, wherein the second opening exposes a top surface of the first floating gate layer and a top surface of a portion of the first isolation structure.

14. The method as claimed in claim 1, wherein a top width of the second isolation structure is less than a top width of the first isolation structure.

15. The method as claimed in claim 1, wherein a thickness of the spacer is equal to a distance of a sidewall of the second floating gate layer beyond a sidewall of the first floating gate layer.

16. The method as claimed in claim 1, wherein after forming the first floating gate layer and before forming the mask layer, the method further comprises:
forming a buffer layer over the first floating gate layer.

17. The method as claimed in claim 16, wherein forming the second opening further comprises:
after removing the mask layer and the spacer, removing the buffer layer to expose a top surface of the first floating gate layer.

18. The method as claimed in claim 1, wherein:
the spacer has different etch selectivity from the first isolation structure and the second isolation structure; and
the mask layer has the same etch selectivity as the spacer.

19. The method as claimed in claim 1, wherein a bottom of the second floating gate layer has an acute angle.

20. The method as claimed in claim 19, wherein the acute angle is greater than degrees and less than 90 degrees.
